(19) United States
(12) Patent Application Publication
(10) Pub. No.: US 2012/0097188 A1
(43) Pub. Date: Apr. 26, 2012

(54) Method and Apparatus for Treating Substrates

(75) Inventors: Heinz Kappler, Dornstetten-Aach (DE); Jorg Lampprecht, Dornhan (DE)

(73) Assignee: Gebr. Schmid GmbH, Freudenstadt (DE)

(21) Appl. No.: 13/340,269

(22) Filed: Dec. 29, 2011

Related U.S. Application Data
(63) Continuation of application No. PCT/EP2010/059589, filed on Jul. 5, 2010.

(30) Foreign Application Priority Data
Jul. 6, 2009 (DE) 102009032217.5

(51) Int. Cl. B08B 3/02; B08B 3/10

(52) U.S. Cl. 134/10; 134/61

(57) ABSTRACT

In the case of a method and an apparatus for treating substrates, resist layers are removed from the substrates by spraying with process solution. The substrates are sprayed with the process solution first in a main stripping module and then in a post-stripping module and the said process solution collects in containers under the modules. At least one container is respectively provided for each module. The process solution is collected in the main stripping module in two containers and first fed directly into a second container, which is largely separated from the first container by a wall, which is liquid-permeable in a region significantly below the surface level of the process solution. Process solution is taken from the first container without froth and returned once again into the cycle of the process for wetting the substrates.

### CROSS-REFERENCE TO RELATED APPLICATIONS

This application is a continuation of PCT Application No. PCT/EP2010/059589, filed Jul. 5, 2010, and claims priority to DE 10 2009 032 217.5 filed Jul. 6, 2009, the disclosures of which are hereby incorporated by reference in their entirety.

### FIELD OF APPLICATION AND PRIOR ART

The invention relates to a method for treating substrates, in particular for the production of photovoltaic modules, and to an apparatus suitable for carrying out this method.

In photovoltaic technology, and in particular PCB technology, resist layers are removed from the corresponding substrates by means of a process solution. This sometimes involves using process solutions, which may froth or, in combination with the resist or other substances with which they come into contact during cleaning, lead to froth formation. Such resists are wax-like hot melts or thermal inks or polymers or inks that can be applied by means of printers or photolithography and screen printing. The said froth formation may lead to interruptions in the process or to malfunctions of the installations, under some circumstances even to the extent that the process solution can no longer be used at all. Froth can also occur in cases where the process solution is recirculated or sprayed onto the substrates and possibly also in a return from a process chamber to a tank or container.

Antifrothing agents are used as additives to reduce froth. However, they are increasingly meeting with disapproval for reasons of cost and environmental protection, since there is an increase in both the total organic carbon (TOC) load of the waste water and the chemical oxygen demand (COD) value, and consequently the discharge values for the waste water are exceeded. This therefore means that the loading of the water with organic substances is too high.

### PROBLEM AND SOLUTION

The invention addresses the problem of providing a method specified at the beginning and an apparatus suitable for carrying it out with which problems of the prior art can be avoided and, in particular, froth formation in the process solution when removing resist layers from substrates can be minimized.

This problem is solved by a method with the features of claim 1 and an apparatus with the features of claim 9. Advantageous and preferred embodiments of the invention are the subject of the further claims and are explained in more detail below. Some of the features enumerated below are only mentioned for the method or only mentioned for the apparatus. However, irrespective of this, it is intended that they can apply both to the method and to the apparatus. The wording of the claims is made the content of the description by express reference.

According to the invention, it is provided that the substrates are first wetted with the process solution in a main stripping module and then in a post-stripping module; it may also be possible to do without the post-stripping module. Process solution collects in containers under the modules or at least in a container under the main stripping module. In this case, at least one container is provided for the post-stripping module, with at least two containers being provided for the main stripping module. Process solution is first fed from the main stripping module directly into a second container, in particular by a pipe that is bent or angled at least once. The second container is substantially separated from the first container of the main stripping module by a wall in between, which however is liquid-permeable as a result of clearances, holes, cutouts or the like in a region significantly below the surface level of process solution located in it. In particular, the liquid permeability is provided as low down as possible in the containers. The two containers may in this case be formed by inserting a wall into a large container, that is to say by separating it. The said clearances or the like are then either provided in the lower region of the wall or else the wall is inserted not quite down to the bottom. Process solution is taken from the first container, in particular pumped out by means of a pump, and returned into the cycle of the process for wetting the substrates.

Consequently, it is thus provided that, in the main stripping module, the process solution collects in a second container and froth is thereby produced on its surface, or froth that is present rises to the surface. As a result of the liquid-carrying connection to the first container, the latter is likewise filled with process solution, but as far as possible without froth. Consequently, process solution that is substantially froth-free can be taken from there for renewed spraying or wetting of the substrates.

To collect the process solution in the main stripping module, under some circumstances also in the post-stripping module, a kind of pan or the like may be provided as a collecting pan, with a lowest point from which a pipe or other line leads into the said container. Such a return pipe can indeed reduce froth formation, or make the froth break down again as far as possible, as a result of the said bending or its shaping in general.

In a further refinement of the invention, it may be provided that froth in the second container, on the surface of process solution located in it, is moved over a side wall of the container, that is to say is taken as it were, into a separate froth pan arranged alongside. This may be performed in various ways, for example with mechanical slides, by blasting with compressed air or by spraying, in particular spraying with process solution itself. The spraying is regarded as advantageous in particular, since in this case not only is the froth as it were mechanically moved but also at least partially broken down or made to disintegrate. In this froth pan there may then likewise once again be process solution with froth on the surface, the process solution once again being taken and advantageously returned into the first container, particularly advantageously once again by pumping. Alternatively, a branch to a waste-water discharge line or treatment may be provided.

To allow better control of the movement of the froth away from the second container into the froth pan, that is to say when the froth is moved over a side wall of the second container, a kind of height-adjustable weir or kind of bulkhead strip may be provided. This can respectively be adjusted in height so as to be located at the height of the liquid level of the process solution or a little above it. This achieves the effect that only froth is pushed over the side and, as far as possible, no process solution.

In an advantageous refinement of the invention, the froth may also be broken down or eliminated in the froth pan by spraying, in particular once again with process solution.

A number of nozzle devices or spraying devices arranged one behind the other may be provided in the direction of movement of the froth towards the froth pan, in order as it were to break down the froth repeatedly and move it well. The individual devices then do not have to be operated with very great pressure, which in turn is advantageous for the movement and the conversion into process solution.

The aforementioned return pipe may be advantageously formed in such a way that it ends below the surface of the process solution in the second container. This allows froth formation during feeding into the second container to be reduced.

A post stripping module may be constructed in a way similar to the main stripping module, that is to say for example be of approximately the same length and also have a first and a second container for the process solution used in it. The post stripping module is advantageously of a shorter and simpler construction and has only a single container. In this in turn, the process solution used in the post stripping module is collected, advantageously in a way similar to in the main stripping module, and then fed into the container. Once again a return pipe described above may be provided for this. With the simplified construction of the post stripping module with only one container, it is possible to return the process solution from there once again into one of the containers of the main stripping module for renewed use there. For this purpose, either once again a liquid-permeable wall may be provided or a wall with clearances or the like. Alternatively, a cascade of the containers may be provided in the post stripping module, transferring process solution while likewise avoiding froth formation as far as possible.

Both in the main stripping module and in the post stripping module, spraying devices or the like for the process solution may be fed from a single container, namely the first container of the main stripping module. The avoidance of froth formation can then concentrate entirely on the process solution in this container.

These and other features emerge not only from the claims but also from the description and the drawings, where the individual features can be realized in each case by themselves or as a plurality in the form of subcombinations in an embodiment of the invention and in other fields and can constitute advantageous and inherently protectable embodiments for which protection is claimed here. The subdivision of the application into individual sections and subheadings does not restrict the general validity of the statements made thereunder.

### BRIEF DESCRIPTION OF THE DRAWINGS

Exemplary embodiments of the invention are illustrated schematically in the drawings and are explained in greater detail below. In the drawings:

FIG. 1 shows a schematic side illustration of an installation according to the invention for treating substrates,

FIG. 2 shows a main stripping module and a post stripping module from FIG. 1 in an enlargement with functional illustrations,

FIG. 3 shows a view of the main stripping module according to FIG. 2 in the direction in which the substrates run through,

FIG. 4 shows a plan view of the illustration corresponding to FIG. 3 and

FIG. 5 shows a view of an immersion bath instead of spray pipes for the substrates in an alternative main stripping module.

### DETAILED DESCRIPTION OF THE EXEMPLARY EMBODIMENTS

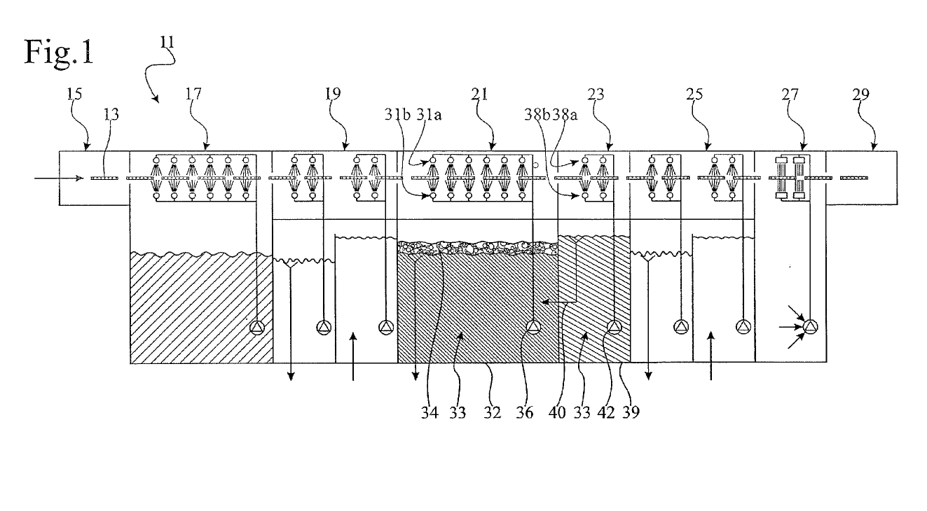

FIG. 1 illustrates an installation 11 according to the invention for treating substrates 13, the substrates 13 advantageously being for solar cells for photovoltaic modules. The installation 11 has in a way known per se an entry module 15, which is adjoined by an etching module 17. There, the structures on the substrates 13 are opened by etching, as is also known, for which reason it does not have to be discussed in any further detail. After the etching module 17 there is a likewise known rinsing module 19.

This is adjoined by a main stripping module 21, as has been explained in general above, which in turn is followed by a post stripping module 23. That in turn is then followed by a second rinsing module 25, a drying module 27 and an exit module 29. Thus, the substrates 13 are treated in a way known per se in the direction of running through from left to right.

The main stripping module 21 has above the substrates 13, or their running-through path, upper spray pipes 31a and, below them, lower spray pipes 31b. These respectively spray process solution 33 onto the substrates 13, which could alternatively also be performed only from one side. As has been described above, the substrates 13 are freed of resist by the sprayed-on process solution 33. Underneath the substrates 13 there is a container 32, in which the process solution 33 finally collects. On the surface of the process solution 33 there is froth 34, which is, as far as possible, to be avoided or eliminated in the manner described below. By means of a pump 36, process solution 33 is pumped out of the container 32 and fed again to the spray pipes 31a and 31b, for the removal of resist layers from the substrates 13.

In the post stripping module 23 there are upper spray pipes 38a and lower spray pipes 38b for the substrates 13. These serve the purpose of removing remains of resist layers from the substrates 13, generally no longer being very great in number. This has the result that only very little or scarcely any froth is produced in the container 39 under the substrates 13 in the post stripping module 23, so that virtually only process solution 33 is contained there. By means of a cascade line 40, such process solution that is substantially froth-free can be fed into the container 32 alongside the mainstream module 21. Furthermore, the spray pipes 38a and 38b can be supplied with process solution 33 by means of a pump 42.

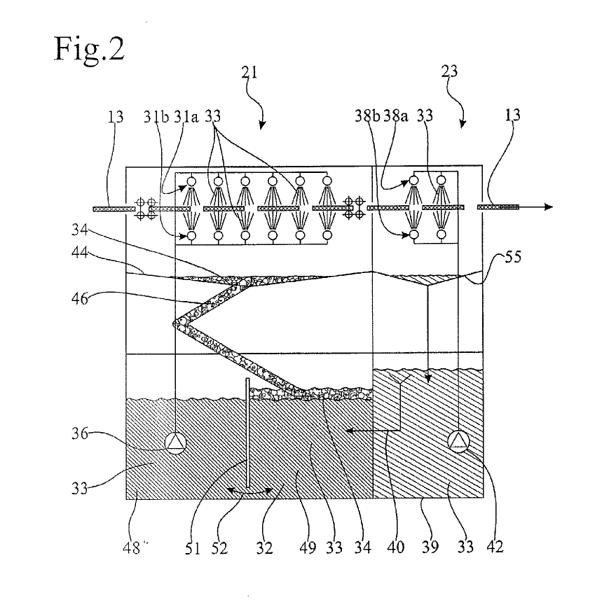

In the detailed illustration according to FIG. 2 it can be seen that underneath the substrates 13 or their running-through path there is a collecting pan 44. This collects all of the process solution 33 discharged from the spray pipes 31a and 31b and feeds it into the container 32 by means of a return pipe 46, to be precise into a second tank container 49 on the right. As illustrated, the return pipe 46 may be bent or kinked one or more times or be formed in some other way to feed process solution 33 that is carried in it into the second tank container 49 froth-free, or with the froth being reduced as much as possible. One end of the return pipe 46 may either end near the surface level of the process solution 33. Alternatively, it may end deeper, which in many cases serves for reducing froth further.

On the surface of the process solution 33 in the second tank container 49 there is a considerable amount of froth 34, since the froth formation is increased here by the fragments of resist detached from the substrates 13. In the container 32, a first tank container 48 is also formed by a separating wall 51. This may be performed simply by inserting the separating wall 51 into the container 32. In this case, an opening 52 is provided in the lower region of the separating wall 51, for example by the separating wall 51 not extending quite down to the bottom. Alternatively, openings or apertures or clearances could also be provided in the separating wall 51. Consequently, the first tank container 48 and the second tank container 49 are connected to each other in a liquid-carrying manner. An exchange of process solution 33 alone, that is to say without froth 34, takes place through the opening 52 in the lower region. This has the effect that only uncontaminated process solution 33, or little froth, is actually contained in the first tank container 48.

Likewise provided in the post stripping module 23, which is illustrated on an enlarged scale, is a collecting pan 55, which can feed the process solution 33 into the container 39 in fact in a very simple manner. Since scarcely any fragments of resist are contained here in the process solution 33, or none at all, froth formation is indeed reduced considerably. Alternatively, a return pipe 46 may be provided in a way similar to in the main stripping module 21. It can be seen that the process solution 33 in the container 39 has no froth.

Furthermore, a cascade line 40 is provided, in order to feed the process solution 33, which is froth-free and substantially resist-free, and consequently still very unused, into the container 32, that is to say as it were to refresh the process solution there. Such a cascade line 40 may, in a way similar to the return line 46, be designed for reducing froth. It may either lead into the first tank container 48 or, as illustrated, lead into the second tank container 49.

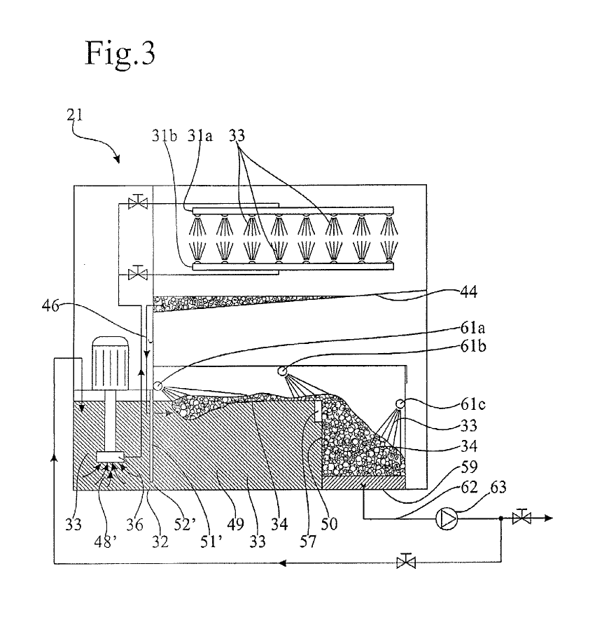

In FIG. 3, a sectional illustration through the main stripping module 21 in the direction in which the substrates run through is shown. It can be seen that froth 34 formed on the second tank container 49 is treated or moved. For this purpose, there is a froth pan 59 alongside the second tank container 49 to the right, separated by a side wall 50. It is intended for the froth 34 to be introduced into this froth pan and broken down, in order that the process solution 33 can be used again. In order that, as far as possible, only froth 34 is transported to the right and no process solution 33 runs out of the second tank container 49, a height-adjustable bulkhead strip 57 is provided. This can be moved up to such a height that it corresponds approximately to the surface level of the uncontaminated process solution 33 in the second tank container 49. Only froth 34 is then still moved to the right over it into the froth pan 59.

For moving the froth 34, pipe-like elongated froth nozzles 61a are provided as spraying devices on the extreme left over the second tank container 49 and froth nozzles 61b near the sidewall 50 or the bulkhead strip 57. These nozzles are called froth nozzles because they are designed for and serve the purpose of moving the froth or even breaking it down. They are not, however, in any way intended to serve for or be conducive to producing froth. The nozzles may have round nozzle openings or elongated openings, for example in the manner of slit nozzles. A plurality or even a multiplicity of such nozzles is provided on elongated pipes, for which reason they are indeed referred to as pipe-like and elongated.

These froth nozzles are all directed to the right and obliquely downwards, that is to say approximately in one direction; the froth nozzles 61a are even at a still shallower angle. They spray process solution 33 out at high pressure as a more or less fine mist, which drives the froth 34 from the surface of the process solution 33 in the second tank container 49 to the right into the froth pan 59 and already breaks it down somewhat, that is to say reduces it.

Above the froth pan 59 there are third froth nozzles 61c, the direction of the jet of process solution 33 of which is obliquely downwards to the left, to be precise as it were onto the entire surface of the froth 34 in the froth pan 59. This does not serve for moving the froth 34 but for breaking it down, so that it again assumes the form of uncontaminated process solution 33. Process solution 33 can then be taken from the froth pan 59 by means of a discharge line 62 and a drainage pump 63 and, depending on the state or resist content, either be passed on for waste-water treatment or else be returned into the cycle.

To the left alongside the second tank container 49 there is a first tank sub-container 48′ of the first tank container 48. It is separated by a separating wall 50′ with an opening 52′ provided in the lower region and has the previously described pump 36, which supplies the spray pipes 31a and 31b.

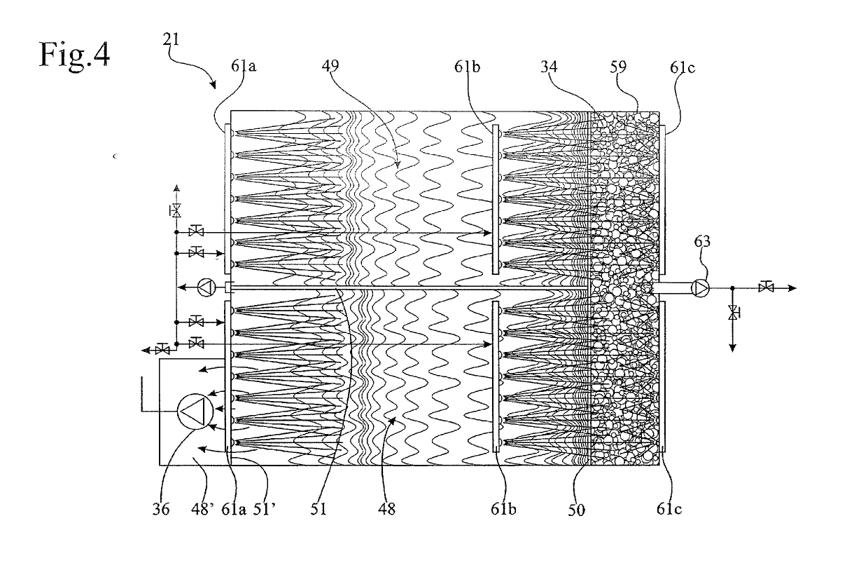

In the plan view according to FIG. 4, it can be seen how froth 34 on the surface of the process solution 33 both over the first tank container 48 and over the second tank container 49 is moved downwards in the illustration and towards the froth pan 59 by means of the froth nozzles 61a and 61b. A separating wall 51 between the first tank container 48 and the second tank container 49 can also be seen. At the top left there is the previously described first tank sub-container 48′, separated from the first tank container 48 by the said separating wall 51′. It can be seen that the side wall 50 runs over the entire width of the first tank container 48 and the second tank container 49 alongside each other, and similarly also the froth pan 59. The same applies to the froth nozzles 61a, 61b and 61c.

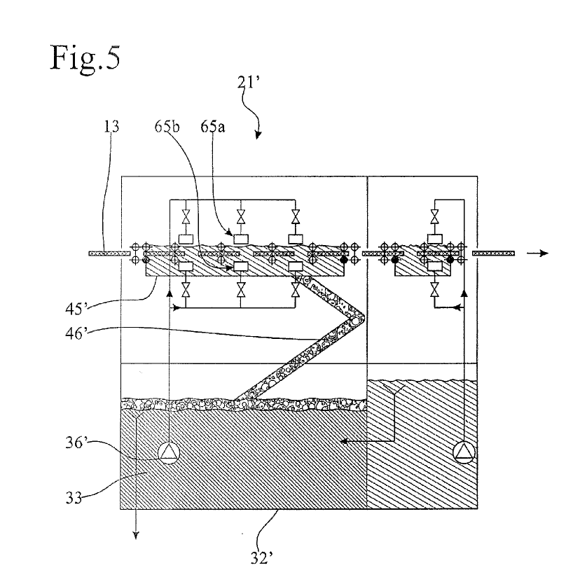

Illustrated in FIG. 5 is a modification of the illustration from FIG. 2 with a main stripping module 21′, in which the container 32′ with process solution 33 in it and the return pipe 46′ correspond to the configuration from FIG. 2. The modification here is that the substrates 13 are not transported as it were freely in the air by a roller transporting path and sprayed by the spray pipes 31, but are taken through an immersion bath 45′. In this case, surge pipes 65a and 65b above and below the substrates serve the purpose of additionally mixing up the process solution 33 even during the immersion, and consequently of intensifying the effect of the treatment. For the upper surge pipes 65a it is provided that they may either be immersed in the process solution 33 or else be partly immersed and partly above it, and can then possibly even also perform a spraying function. The surge pipes 65a and 65b are supplied by means of a pump 36′ in the liquid container 32′.

FIG. 5 reveals that the principle of the immersion bath is also realized here in the case of the post-stripping module to the right thereof, which however does not necessarily have to be the case. Therefore, a precise explanation is not given here. The treating of substrates in an immersion bath instead of by spraying is known in principle. In this respect, the technical implementation is also not difficult for a person skilled in the art. The advantage here is, in particular, that little froth is produced in the chamber of the main stripping module 21. Combinations of these techniques are also possible.

Illustrated here is the application of the invention in individual process chambers or modules in which the substrates are sprayed or immersed in a continuous treatment bath or immersion bath. It may, however, also be advantageously used in the case of baths with standing waves, so that wetting can take place over the surface area without immersion. An effective application of the invention may also be obtained in combination with ultrasound.

1. A method for treating flat substrates, wherein said substrates have resist layers, the method comprising the steps of:
removing said resist layers from said substrates by spraying or wetting with a process solution first in a main stripping module and then in a post stripping module;
providing at least one container beneath each stripping module for collecting said process solution therein, wherein said containers of each said stripping module are separated from one another; and
collecting said process solution in said main stripping module in first and second containers and, in a first step, feeding said collected process solution directly into said second container, which is substantially separated from said first container by a wall, wherein said wall is liquid-permeable as a result of clearances or holes in a region significantly below a surface level of process solution located in said second container,
wherein in a following step some of said process solution is taken from said first container and reused into said removing step for wetting said substrates.

2. The method according to claim 1, wherein said process solution is fed into said second container in a return pipe from a collecting device in flat form in said main stripping module.

3. The method according to claim 2, wherein froth formation is reduced by shaping said return pipe with at least one bend.

4. The method according to claim 2, wherein said return pipe ends below said surface level of said process solution in said second container.

5. The method according to claim 1, wherein froth in said second container, on said surface of said process solution, is moved with spraying devices over a side wall of said container into a separate froth pan arranged alongside, wherein disintegrated froth or cleaning s process solution is taken out of said froth pan and returned into said first container.

6. The method according to claim 5, wherein said froth in said froth pan is also sprayed with process solution from above by means of spraying devices for breaking down said froth or eliminating said froth and converting it into process solution.

7. The method according to claim 1, wherein process solution from said post stripping module or from said container provided beneath said post stripping module is directed into said second container in said main stripping module.

8. The method according to claim 7, wherein said process solution is directed in said main stripping module via at least one cascade.

9. An apparatus for treating flat substrates, wherein said substrates have resist layers, comprising:
a main stripping module and a downstream post-stripping module; and
spraying devices or wetting devices for applying process solution to said substrates in a transporting path through said stripping modules,
wherein said main stripping module has a first container and a second container for collecting said process solution, with process solution being fed into said second container after having been collected, and
wherein said second container is largely separated from said first container by a liquid-permeable wall having clearances or holes in a region significantly below a surface level of said process solution therein.

10. The apparatus according to claim 9, wherein a collecting device of flat form is provided in said main stripping module with a return pipe leading into said second container.

11. The apparatus according to claim 10, wherein said collecting device is leading below said surface level of said process solution therein.

12. The apparatus according to claim 11, wherein said collecting device is leading into a lower third of said second container.

13. The apparatus according to claim 10, wherein said return pipe is designed for reducing froth formation of said process solution flowing through.

14. The apparatus according to claim 13, wherein said return pipe is designed for reducing said froth formation by providing at least one bend in said return pipe.

15. The apparatus according to claim 9, wherein spraying devices are provided above said containers in said main stripping module, said spraying devices having a spraying direction towards a side region of at least one of said containers, wherein a froth pan is arranged in said side region for collecting froth having been moved over a side wall of said container.

16. The apparatus according to claim 15, wherein said spraying devices have a spraying direction towards a side region of both said containers.

17. The apparatus according to claim 15, wherein a further spraying device is directed into said interior of said froth pan for breaking down said froth located therein as process solution.

18. The apparatus according to claim 9, wherein an immersion bath is provided with process solution for said substrates in said main stripping module as a wetting device.

19. The apparatus according to claim 18, wherein an immersion bath is also provided in said post-stripping module.

20. The apparatus according to claim 18, wherein an overflow from said immersion bath into said second container is provided.

21. The apparatus according to claim 18, wherein surge pipes are provided above and below a path for said substrates through said immersion bath for specifically directed application or wetting with said process solution.

22. The apparatus according to claim 9, wherein a cascading line is provided from a container for collecting said process solution in said post-stripping module into said second container of said main stripping module.
